(19) United States
(12) Patent Application Publication
(10) Pub. No.: US 2010/0025707 A1
(43) Pub. Date: Feb. 4, 2010

(54) Optical Element, Radiation-Emitting Component and Method for Producing an Optical Element

(76) Inventor: Stefan Groetsch, Lengfeld-Bad Abbach (DE)

Correspondence Address: SLATER & MATSIL, L.L.P., 17950 PRESTON RD, SUITE 1000, DALLAS, TX, 75252-5793, US

(21) Appl. No.: 12/442,641

(22) PCT Filed: Sep. 26, 2007
(86) PCT No.: PCT/DE07/01736

§ 371 Date: Jun. 4, 2009

(30) Foreign Application Priority Data
Sep. 29, 2006 (DE) 10 2006 046 301.3

(51) Int. Cl. H01L 33/58; B29D 11/00; G02B 3/00

(52) U.S. Cl. 257/98; 264/1.7; 359/811; 257/E33.068

(57) ABSTRACT

An optical element comprising includes a base body containing a base material, and a filling body containing a filling material, wherein the filling body adheres to the base body. A radiation-emitting component and a method for producing an optical element are futhermore described.

This patent application claims the priority of German patent application 10 2006 046 301.3 filed on Sep. 29, 2006, which is hereby incorporated by reference.

### TECHNICAL FIELD

The invention relates to an optical element and a radiation-emitting component comprising an optical element. The invention furthermore relates to a method for producing an optical element.

The published patent application DE 199 45 675 A1 discloses a surface-mountable LED housing in which an LED chip is arranged. Disposed downstream of the chip is a lens containing a thermoplastic material.

In the case of a thermoplastic material, in the case of thermal stress that occurs for example during a soldering operation, there is the risk of deformation of the lens and furthermore the risk of opacity of the lens. These influences can adversely influence the optical properties of the lens.

### SUMMARY

In one aspect, the present invention specifies an optical element which has comparatively stable optical properties despite thermal stress.

In a further aspect, the present invention specifies a radiation-emitting component which has comparatively stable optical properties despite thermal stress.

In a further aspect, the present invention specifies a method by means of which the optical element can be produced in a simple manner.

Advantageous developments of the optical element and of the radiation-emitting component and also advantageous configurations of the method are also specified herein.

An optical element according to the invention comprises a base body containing a base material, and a filling body containing a filling material, wherein the filling body adheres to the base body.

Preferably, the optical element is provided for shaping radiation. By way of example, the optical element can be an imaging optical unit.

Particularly preferably, the base body forms an outer region of the optical element, while the filling body forms an inner region of the optical element.

Further preference is given to the fact that the base material differs from the filling material. This has the advantage that a suitable material can be used depending on the different requirements made of the base body and the filling body.

In a particular variant of the optical element, the base body has a cavity filled with the filling material, wherein the form of the filling body is determined by the cavity. By means of filling the base body, it is advantageously possible to create an optical element whose base body and filling body are irreversibly connected to one another. By means of the base body and filling body, the optical element has two regions which can differ in terms of their optical properties.

In one preferred variant of the optical element, the base body has the form of a body of revolution. In particular, the filling body can also have the form of a body of revolution. By way of example, a contour of the optical element can be approximately dome-like. In this case, the contour of the base body can be like a sphere segment or ellipse segment at least in sections. By way of example, the base body can be shaped for instance in the manner of a spherical shell segment. In particular, the base body can have the form of a hemispherical shell with an opening region for filling the base body with filling material. The filling body then has approximately the form of a hemispherical interior. As an alternative, the form of the filling body can correspond approximately to an inverted truncated cone surrounded by the base body in ring-like fashion.

In particular, the filling body and the base body have a common axis of symmetry. Preferably, the opening region also has this axis of symmetry. Particularly preferably, the opening region, together with a surface of the base body that surrounds the opening region, forms a radiation passage area of the optical element.

Furthermore, the radiation passage area can comprise a concavely curved or planar partial region and a convexly curved partial region that at least partly surrounds the concavely curved partial region at a distance from the optical axis, wherein the optical axis runs through the concavely curved partial region. In particular, the opening region can be concavely curved and the surrounding surface can be convexly curved.

In accordance with one preferred embodiment, the filling material is transmissive to the radiation to be shaped. This has the advantage that the radiation can pass through the filling body and the filling body can thus contribute to the beam shaping.

The filling material preferably contains transparent potting substances or resins. By way of example, the filling material can contain a silicone material. Furthermore, it is possible to use a silicone gel that proves to be advantageous with regard to cycling durability, heating during the soldering operation, ageing stability and radiation resistance, particularly in the case of thermal or mechanical stress. Under the action of heat, the opening region permits an expansion of the filling material. Since the base body forms the optically more critical region of the optical element, a deformation of the filling body leads to a negligible change in the optical properties of the optical element.

Further suitable filling materials are for example hybrid materials such as e.g. mixtures of epoxy resins and silicone resins, since they have the advantages over silicone resins of shorter curing times and better releasability from the mold and the advantage over epoxy resins of increased UV stability.

In accordance with a further configuration, the base material is transmissive to the radiation to be shaped. Consequently, the radiation can pass through the base body and the base body can thus contribute to the beam shaping. By way of example, the base material can contain glass. Preferably, a glass material is used which is resistant at temperatures of greater than 300° C., that is to say that neither material alterations, for example opacities or discolorations, nor deformations are to be feared at these temperatures. These temperatures can prevail for a number of hours.

Furthermore, the base material can contain a plastic material. The base material is preferably a thermoplastic. Suitable thermoplastics include for example polycarbonates (PC) or polymethacrylmethylimides (PMMI).

The optical element according to the invention can be a refractive, diffractive or dispersive element.

Preferably, the optical element, which is for example part of a radiation-emitting semiconductor component, is solderable at temperatures of between 200° C. and 300° C. Neither material alterations, for example opacities or discolorations, nor deformations are to be feared in this temperature range. These temperatures typically occur for a few minutes.

A radiation-emitting component according to the invention has an optical element as described above and at least one radiation-emitting semiconductor body which is embedded into the filling body.

Advantageously, by means of the filling body, not only an optical effect but furthermore a protective effect for the semiconductor body can be obtained. The filling body can serve as a potting.

In accordance with one particular configuration, the semiconductor body comprises a semiconductor material based on nitride compound semiconductors. In the present context, “based on nitride compound semiconductors” means that the active epitaxial layer sequence or at least one layer thereof comprises a nitride III/V compound semiconductor material, preferably AlₙGaₘIn₁₋ₙ₋ₘN, where 0≦n≦1, 0≦m≦1 and n+m≦1. In this case, this material need not necessarily have a mathematically exact composition according to the above formula. Rather, it can have one or more dopants and also additional constituents which essentially do not change the characteristic physical properties of the AlₙGaₘIn₁₋ₙ₋ₘN material. For the sake of simplicity, however, the above formula comprises only the essential constituents of the crystal lattice (Al, Ga, In, N), even if these can be replaced in part by small quantities of further substances.

Preferably, the refractive index of the filling material is adapted to the refractive indices of the base material and more extensively of the semiconductor material. In particular, the filling material has a refractive index of 1.3 to 1.7.

In accordance with a further configuration, the semiconductor body is a thin-film light emitting diode chip. A thin-film light emitting diode chip is distinguished in particular by at least one of the following characteristic features:

a reflective layer is applied or formed at a first main area—facing toward a carrier element—of a radiation-generating epitaxial layer sequence, said reflective layer reflecting at least part of the electromagnetic radiation generated in the epitaxial layer sequence back into the latter;

the epitaxial layer sequence has a thickness in the region of 20 μm or less, in particular in the region of 10 μm; and

the epitaxial layer sequence contains at least one semiconductor layer having at least one area having an intermixing structure which ideally leads to an approximately ergodic distribution of the light in the epitaxial layer sequence, that is to say that it has an as far as possible ergodically stochastic scattering behavior.

A basic principle of a thin-film light emitting diode chip is described for example in I. Schnitzer et al., Appl. Phys. Lett. 63 (16), Oct. 18, 1993, 2174-2176, the disclosure content of which in this respect is hereby incorporated by reference.

A thin-film light emitting diode chip is to a good approximation a Lambertian surface emitter and is therefore particularly well suited to the application in a headlight.

Expediently, in the case of the radiation-emitting component according to the invention, the radiation-emitting semiconductor body is arranged on a carrier. By way of example, the carrier can be a plate containing a ceramic material, for instance. In particular, the carrier can have electrical connection regions for supplying the semiconductor body with power.

In one preferred variant of the radiation-emitting component, the base body is applied to the carrier. By way of example, the contour of the base body can be like two “S” facing one another, which means that the contour line has two points of inflection. In this case, only a marginal end of the base body lies on the carrier, while the rest of the base body is elevated above the carrier. As an alternative, the contour of the base body can be like two circle segments facing one another, in particular two quarter-circles.

In one particularly preferred variant, the base body is connected to the carrier by means of the filling material. In particular, the base body adheres on the carrier by means of the filling material. An adhesion agent or the application of an adhesion agent can advantageously be obviated as a result of this.

In accordance with a further embodiment, the base body has on a side facing the carrier at least one projecting fixing element for fixing the optical element. The fixing element can be embodied for example in the manner of a pin.

The fixing element can serve for fastening the optical element in the carrier or a further element, for example a heat sink, disposed downstream of the carrier. In particular, the carrier or the further element has a suitable plug-in device for mechanically fastening the fixing element.

Furthermore, a spacer can be arranged between the optical element and the carrier, said spacer preferably surrounding the semiconductor body in ring-like fashion. The spacer can prevent excessive heating of the optical element. At the same time, the ring-like spacer can serve as a filling frame for embedding the semiconductor body in filling material.

Preferably, a heat sink is provided as a further element, said heat sink serving for dissipating heat from the component and containing Al, for example. This reduces the risk of deformations or material alterations of the optical element and hence the risk of the impairment of the optical properties such as emission characteristic or coupling-out efficiency.

The radiation-emitting component preferably has an SMT (Surface Mounted Technology) design. This enables comparatively simple mounting of the component.

It is conceivable for the component to comprise at least three semiconductor bodies that respectively emit red, green and blue light. The light generated can be mixed by means of the optical element.

The radiation-emitting component according to the invention is suitable for backlighting and illumination purposes.

The optical element according to the invention can be produced in a simple manner. Preferably, firstly the base body is produced, said base body comprising a fillable cavity. The filling material, which contains a gel for example, can be filled into the cavity by means of an opening region of the base body, whereby the filling body is formed.

By way of example, the base body can be molded from a glass material by means of a deep-drawing method.

Advantageously, the optical properties of the optically critical base body can be substantially maintained as a result of the thermal stability of the glass material even with high heat supply.

Furthermore, the base body can be produced from a plastic material by means of an injection molding or transfer molding method. By way of example, the base body can be produced from a thermoplastic material, while the filling body is formed from a silicone material.

Upon heating, the filling material can advantageously expand in a direction of the opening region.

In accordance with one preferred variant for producing the radiation-emitting component according to the invention, the already fabricated base body is applied to the carrier. The size of the opening region can be adapted to the number of semiconductor bodies to be mounted in such a way that it is possible for the semiconductor bodies to be mounted through the opening region.

### BRIEF DESCRIPTION OF THE DRAWINGS

Further preferred features, advantageous configurations and developments and also advantages of an optical element and of a radiation-emitting component according to the invention will become apparent from the exemplary embodiments explained in more detail below in connection with FIGS. 1 and 2.

In the figures:

FIG. 1 shows a schematic cross-sectional view of a first exemplary embodiment of a radiation-emitting component according to the invention,

FIG. 2 shows a schematic cross-sectional view of a second exemplary embodiment of a radiation-emitting component according to the invention.

### DETAILED DESCRIPTION

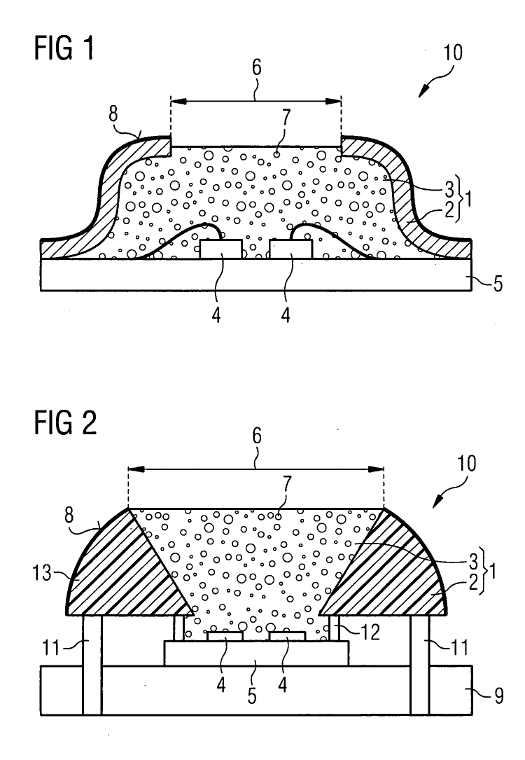

In the case of the radiation-emitting component 10 illustrated schematically in figure 1, an optical element 1 and two radiation-emitting semiconductor bodies 4 are shown in cross section. The semiconductor bodies 4 are embedded into a filling body 3 comprising a filling material 7. The filling body 3 is only partly surrounded by a base body 2. The base body 2 has an opening region 6 in the region of the semiconductor bodies 4. It is thereby possible to arrange the semiconductor bodies 4 on a carrier 5 through the opening region 6 after mounting of the base body 2. Furthermore, the opening region 6 serves for filling the base body 2 with the filling material 7, which is preferably gel-like during the filling process. The base body 2 is dimensionally stable in this case. The base body 2 and the carrier 5 delimit a cavity that is filled with the filling material 7. The filling body 3 is formed thereby. The filling body 3 is transmissive to radiation generated by the semiconductor bodies 4.

In this embodiment, the filling material 7 arranged between the base body 2 and the carrier 5 has an adhesive effect and can therefore serve as an adhesion agent that holds together the base body 2 or the optical element 1 and the carrier 5.

The filling material 7 preferably contains a silicone gel.

A radiation passage area 8 of the optical element 10 is composed of a surface of the base body 2 that surrounds the opening region 6 and a surface of the filling body 3 that is arranged within the opening region 6.

In this exemplary embodiment, the base body 2 comprises a glass material and can be produced by means of a deep-drawing method. The glass material is particularly suitable for the optically critical region since it is dimensionally stable and material-stable even at temperatures of greater than 300° C. These temperatures can occur for up to a number of hours during the production and mounting of the radiation-emitting component 10.

In the case illustrated, the carrier 5 is a plate preferably comprising a ceramic material with advantageous thermal properties for sufficient cooling of the component 10. The optical element 10 is elevated above the carrier 5 in dome-like fashion. In particular, the contour of the base body 2 is like two “S” facing one another, which means that the contour line has two points of inflection. Only a marginal end of the base body 2 touches the carrier 5.

The carrier 5 can have electrical connection regions for supplying the semiconductor bodies 4 with power, the semiconductor bodies 4 being electrically conductively connected to said connection regions.

The filling body 3 in accordance with this exemplary embodiment advantageously has a protective effect, and can therefore serve as a potting for the semiconductor bodies 4.

FIG. 2 shows a radiation-emitting component 10 comprising a carrier 5 and an optical element 1 comprising fixing elements 11 on a side facing the carrier 5. Said fixing elements 11 are provided for fastening the optical element 1 in a further element 9. The further element 9 comprises depressions into which the fixing elements 11 shaped in pin-like fashion engage. The fixing elements 11 are preferably formed in one piece with the base body 2. Production can be effected by means of injection molding, for example, wherein the base body 2 and the fixing elements 11 are preferably produced from a thermoplastic material.

Since the thermoplastic material is more readily deformable in comparison with the glass material upon heating, the radiation-emitting component 10 advantageously has a heat sink for dissipating heat. In particular, the further element 9 on which the carrier 5 is arranged is a heat sink. As illustrated, the heat sink can be a plate which preferably contains a metal, for example Al.

The optical element 1 can be spaced apart from the carrier 5 by means of a spacer 12. As an alternative, the optical element 1 can be seated on the carrier 5, in which case the base body 2 then circumferentially surrounds the semiconductor bodies 4. The spacer 12 is filled with the filling material 7 in the same way as a cavity delimited on the inside by the base body 2. In this exemplary embodiment, too, the filling material 7 can contain a silicone gel. Alongside the optical effect, a protective effect for the semiconductor bodies 4 can be obtained by means of the filling body 3 in which the semiconductor bodies 4 are arranged.

The refractive index of the filling material 7 is preferably adapted to the refractive index of the base material 13 and to the refractive index of the semiconductor material used for the semiconductor bodies 4.

Despite cooling of the component 10, a deformation of the optical element 1 can occur in the exemplary embodiment illustrated in FIG. 2. The filling body 3 can advantageously expand upward through the opening region 6.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or exemplary embodiments.

1. An optical element comprising
a base body containing a base material, and
a filling body containing a filling material, wherein
the filling body adheres to the base body.

2. The optical element as claimed in claim 1, wherein the optical element is provided for shaping radiation.

3. The optical element as claimed in claim 1, wherein the base material differs from the filling material.

4. The optical element as claimed in claim 1, wherein the base body comprises a cavity filled with the filling material, wherein the filling body has a form that is determined by the cavity.

5. The optical element as claimed in claim 1, wherein the base body has the a form of a body of revolution.

6. The optical element as claimed in claim 1, wherein the filling body has the a form of a body of revolution.

7. The optical element as claimed in claim 5, wherein the filling body and the base body have a common axis of symmetry.

8. The optical element (as claimed in claim 1, wherein the base body comprises an opening region for filling with the filling material, said opening region, together with a surface of the base body that surrounds the opening region, forming a radiation passage area of the optical element.

9. The optical element as claimed in claim 2, wherein the filling material is transmissive to the radiation to be shaped.

10. The optical element as claimed in claim 9, wherein the filling material comprises a silicone material.

11. The optical element as claimed in claim 2, wherein the base material is transmissive to the radiation to be shaped.

12. The optical element as claimed in claim 1, wherein the base material contains comprises glass.

13. The optical element as claimed in claim 1, wherein the base material comprises a plastic material.

14. The optical element as claimed in claim 13, wherein the base material comprises a thermoplastic material.

15. The optical element as claimed in claim 1, wherein the base body is formed like a spherical shell segment.

16. The optical element as claimed in claim 1, wherein the base body is formed in ring-like fashion.

17. The optical element as claimed in claim 1, wherein the optical element is a refractive, diffractive or dispersive element.

18. The optical element as claimed in claim 1, wherein the optical element is solderable at temperatures of between 200° C. and 300° C.

19. A radiation-emitting component, comprising:
an optical element comprising a base body comprising a base material, and a filling body comprising a filling material, wherein the filling body adheres to the base body; and
at least one radiation-emitting semiconductor body.

20. The radiation-emitting component as claimed in claim 19, wherein the radiation-emitting semiconductor body is embedded into the filling body.

21. The radiation-emitting component as claimed in claim 19, wherein the refractive index of the filling material is adapted to the refractive index of the base material.

22. The radiation-emitting component as claimed in claim 19, wherein the refractive index of the filling material is adapted to the refractive index of a semiconductor material used for the semiconductor body.

23. The radiation-emitting component as claimed in claim 19, further comprising a carrier wherein the radiation-emitting semiconductor body is arranged on the carrier.

24. The radiation-emitting component as claimed in claim 23, wherein the base body is applied to the carrier.

25. The radiation-emitting component as claimed in claim 24, wherein the base body is connected to the carrier by means of the filling material.

26. The radiation-emitting component as claimed in claim 24, wherein the base body adheres on the carrier by means of the filling material.

27. The radiation-emitting component as claimed in claim 19, wherein the base body comprises at least one projecting fixing element on a side facing the carrier.

28. The radiation-emitting component as claimed in claim 27, wherein the fixing element is provided for fastening the optical element in the carrier or a further element disposed downstream of the carrier.

29. A method for producing an optical elements, the method comprising:
forming the base body comprising a base material,
filling a filling material into the base body, so that a filling body is formed, the filling body adhering to the base body.

30. The method as claimed in claim 29, wherein the base body is produced from the base material by means of a deep-drawing method.

31. The method as claimed in claim 29, wherein the base body is produced from the base material by means of injection molding.
